(19) United States
(12) Patent Application Publication
(10) Pub. No.: US 2006/0290387 A1
(43) Pub. Date: Dec. 28, 2006

(54) Integrated semiconductor memory

(76) Inventors: Timo Gossmann, Neubiberg (DE); Markus Schimper, Moosinning (DE)

Correspondence Address: BAKER BOTTS, L.L.P., 98 SAN JACINTO BLVD., SUITE 1500, AUSTIN, TX, 78701-4039, US

(21) Appl. No.: 11/425,916

(22) Filed: Jun. 22, 2006

(30) Foreign Application Priority Data
Jun. 23, 2005 (DE) 10 2005 029 261.5

(51) Int. Cl. H03K 5/22

(52) U.S. Cl. 327/63

(57) ABSTRACT

An integrated semiconductor circuit has a tunable resistor circuit whose total resistance value can be altered, the total resistance value being stipulated by a digital control word. A comparator compares a first voltage applied to the tunable resistor circuit with a second voltage applied to an external resistor element. A trimmer is coupled to the comparator and to the resistor circuit and provides the digital control word for the tunable resistor circuit. The trimmer determines that digital control word for which the resistor circuit has a total resistance value at which the first voltage is in a prescribed ratio to the second voltage.

### CROSS-REFERENCE TO RELATED APPLICATIONS

This application claims priority to German application number 10 2005 029 261.5 filed Jun. 23, 2005, the contents of which is hereby incorporated by reference in its entirety.

### BACKGROUND

The present invention relates to an integrated semiconductor circuit with a resistor circuit.

### SUMMARY

An integrated semiconductor circuit may comprise a tunable resistor circuit whose total resistance value can be altered, the total resistance value being stipulated by a digital control word; a comparator comparing a first voltage applied to the tunable resistor circuit with a second voltage applied to an external resistor element; and a trimmer being coupled to the comparator and to the resistor circuit and providing the digital control word for the tunable resistor circuit; wherein the trimmer determines that digital control word for which the resistor circuit has a total resistance value at which the first voltage is in a prescribed ratio to the second voltage.

### BRIEF DESCRIPTION OF THE FIGURES

Exemplary embodiments of the invention are explained in more detail below with reference to the drawing, in which

FIG. 1 shows a schematic illustration of a resistor circuit which can be used in an integrated semiconductor circuit based on an embodiment;

FIG. 2 shows a schematic illustration of the integrated semiconductor circuit based on an embodiment; and

FIG. 3 shows a schematic illustration of a switchable connection for an external resistor element to the integrated semiconductor circuit based on an embodiment.

### DETAILED DESCRIPTION

In an integrated semiconductor circuit, for example for use in the analog radio frequency or mixed signal range, high demands are frequently placed on a resistor arranged in the integrated semiconductor circuit. Resistors together with capacitors are thus used for frequency selection in electrical filters, for example. Resistors are also used to produce defined currents. In both applications of integrated resistors, ensuring a good manner of operation requires knowledge of precise resistance values. An integrated resistor can be fabricated in different ways during the processing of the integrated semiconductor circuit. By way of example, diffusion resistors, polysilicon resistors or metal resistors—in each case in different designs—are thus usual.

Depending on its design, a resistor has a temperature response. This means that it exhibits an at least weak dependency in its resistance value on temperature. When developing and fabricating integrated semiconductor circuits, appropriate measures can be taken to ensure that a plurality of identical circuit components, e.g. resistors of the same orientation with the same dimensions, behave approximately in the same way on a semiconductor chip comprising the integrated semiconductor circuit. This is exhibited in an identical temperature response or, by way of example, in an identical current density when the semiconductor chip is aged. Although this “matching” worsens as the interval of the circuit components from one another in the integrated semiconductor circuit increases, as the dimensions of the circuit components decrease or as a result of other factors, for example, the relative fluctuations among a plurality of resistors in a semiconductor chip are relatively small. In contrast to this, it is very difficult to guarantee absolutely demanded resistance values during fabrication. Fluctuations of up to 20% from the nominal resistance value prescribed by the design of the integrated semiconductor circuit are usual in today's fabrication processes for integrated semiconductor circuits.

It is a usual measure, with very high demands on the accuracy of the integrated resistors, to trim said resistors in the finished integrated semiconductor circuit, for example using laser trimming or using electrical fused circuits, i.e. to calibrate them to a demanded resistance value. However, this approach is expensive in terms of the process management, because electrical fuses or laser fuses need to be provided. The calibration for the trimming additionally requires increased complexity because measuring and using the fuse elements achieves the target value of the resistance value only iteratively.

Another possible way of obtaining as accurate a resistance value as possible for the internal resistors in a semiconductor chip is to connect the semiconductor chip to an external resistor. This external resistor can be chosen to have a very narrow tolerance value for its resistance value. However, it needs to be connected by means of a connection provided on the integrated semiconductor circuit or by means of a pin provided on the package of the semiconductor component. Often, a plurality of internal resistance values with different characteristics are required. It may thus be necessary for the resistance value to be kept constant over a particular temperature range or, in a departure therefrom, for the resistance value to respond proportionally to a temperature change within a temperature range. As a result, there need to be a plurality of pins available for connecting the external resistor to a semiconductor chip. Typically, however, the number of available connections is limited, which means that it is a drawback if a plurality of connections need to be used for an addressed function.

In line with one embodiment, an integrated semiconductor circuit is provided which, through the lowest possible number of external connections which need to be provided, allows the most precisely possible defined reference resistance value to be set for resistor elements in the integrated semiconductor circuit or low-complexity calibration of resistors in the integrated semiconductor circuit.

An integrated semiconductor circuit based on an embodiment has a resistor circuit whose total resistance can be altered, the total resistance being stipulated by a digital control word. It also has a comparator for comparing a first voltage applied to the tunable resistor circuit with a second voltage applied to an external resistor element. The comparator and the resistor circuit have a trimmer coupled to them which provides the digital control word for the tunable resistor circuit. The trimmer is set up such that it determines the digital control word for which the resistor circuit has a total resistance at which the first voltage is in a prescribed ratio to the second voltage.

In line with an embodiment, the integrated semiconductor circuit is set up such that the comparator can be used to trim the total resistance value to a resistance value of the external resistor element. To this end, a change in the digital control word alters the total resistance value. The trimming can be effected such that the total resistance value is identical to the resistance value. It is likewise conceivable for trimming to be effected such that the total resistance value is in a particular ratio, for example in the form of a multiple or in the form of a fraction, to the resistance value. The trimming is able to determine that digital control word which causes the total resistance value to be in the prescribed ratio to the resistance value. Following the trimming, it is no longer necessary for the external resistor element to be present in order to provide the most precisely defined reference resistance value possible for resistor components in the integrated semiconductor circuit.

In one embodiment, the integrated semiconductor circuit is calibrated in this way just using an external resistor element. This is done under various ambient conditions, for example, by altering the temperature, the stress or ageing phenomena or other variables during calibration. During continued operation, it is possible to dispense with the external resistor element. This means that connections for just a single external resistor element are required, for example, so that the number of connections which need to be provided is reduced to a minimum.

Advantageously, the resistor circuit can be used during continued operation as a reference resistance for further resistor components or resistor circuits provided in the integrated semiconductor circuit. All in all, low-complexity calibration of resistors is thus made possible for the integrated semiconductor circuit.

In an integrated semiconductor circuit based on one embodiment, a memory is provided for storing the digital control word. This means that it is possible, during operation of the integrated semiconductor circuit, to trim further resistor components using the resistor circuit as reference resistance. The memory may be designed as a volatile memory. In the further case where the memory is in the form of a nonvolatile memory, for example in the form of an E-fuse circuit, EEPROM or MRAM, the digital control word can be read again and used following termination of the operation of the integrated semiconductor circuit and fresh startup.

It is conceivable for the memory to be set up such that an association between a plurality of control words and respective calibrated total resistance values can be stored. It is therefore possible to use the resistor circuit as reference resistance with various calibrated reference resistance values.

Similarly or in addition, it is conceivable for the memory to be set up such that an association between a plurality of control words and different magnitudes of ambient variables, such as temperature values, can be stored. The provision of this measure allows one or more temperature characteristics to be retrieved for the total resistance value.

In another or an additional development of the integrated semiconductor circuit, said circuit has a current source which can be coupled to the resistor circuit and to the external resistor element. This allows the current source to be used when trimming the resistor circuit to the external resistor element. It is established beyond doubt that the resistor circuit and the external resistor element produce a prescribed electrical current which is possibly the same in both elements.

Provision may be made for the resistor circuit and the external resistor element to be connected in parallel to a ground connection. Advantageously, the first voltage applied to the resistor circuit and the second voltage applied to the external resistor element are subject to the same fluctuations in the current source, which means that trimming is performed with a high quality factor for the reference resistance value.

In one embodiment, the integrated semiconductor circuit has a connection which can be used to couple the external resistor element to the integrated semiconductor circuit. The connection is set up such that the current source and the comparison device can be connected to it. If the current source and the comparator are connected to the connection then the current source and the comparator can be coupled to the external resistor element in order to trim the resistor circuit to the external resistor element. As a result of the current source and the comparison device being decoupled from the connection, the connection is available for other tasks or purposes. By way of example, the connection is available for transmitting data signals or control signals to the integrated semiconductor circuit. In the same way, the connection is also available for providing output signals from the integrated semiconductor circuit. The use of the connection for another purpose is not restricted in any way. Advantageously, it is therefore not necessary to provide a separate connection for the purpose of providing a reference resistance.

In one exemplary embodiment of the integrated semiconductor circuit, said circuit has a second resistor circuit, where a second total resistance value is stipulated by a digital second control word and where the second digital control word is derived from the digital control word. Ideally, the second resistor circuit has the same or a similar design and hence a similar temperature response, for example, as/to the resistor circuit. This can be achieved by resistor elements of the same orientation with the same dimensions in the integrated semiconductor circuit, for example. This has the associated advantage that when the resistor circuit has been trimmed to the external resistor element and the second control word has subsequently been stipulated from the digital control word determined by the trimming the second resistor circuit is also available as reference resistance in addition to the resistor circuit. It is conceivable for the second resistor circuit to have a different temperature response than the resistor circuit or to age differently from the resistor circuit given the same current density, for example. Ideally, the resistor circuit and the second resistor circuit have the same properties, however.

In another refinement of the integrated semiconductor circuit, the tunable resistor circuit has a series circuit comprising resistor elements, and at least one resistor element is arranged in the series circuit so as to be able to be switched such that the total resistance value of the resistor circuit can be altered by selecting a switching state.

In this context, it is conceivable to provide a series circuit comprising resistor elements of identical design, so that the total resistance value of the resistor circuit is obtained from the sum of the resistance values of the individual resistor elements. To allow accurate calibration of the total resistance value, individual resistor elements are connected in series in a number such that the sum of the individual resistance values produces a nominal value of 20 percent more than the required total resistance value, for example. At least to some extent, the individual resistor elements can then be shorted using switches in order to match the resistance value of the entire arrangement to a target value. The switches for their part may be in the form of MOS switches or MOS transfer gates. The resistance values of the individual resistor elements are chosen to be identical, for example.

It is likewise conceivable for the resistor circuit to be made up of a parallel circuit comprising individual resistor elements or of a mixture of series and parallel circuits comprising individual resistor elements.

Advantageously, the total resistance value of the resistor circuit is therefore made up on the basis of the resistance values of individual resistor elements which are chosen arbitrarily, and which are produced with a high level of accuracy in terms of the process management in the same way over the entire integrated semiconductor circuit.

Overall, the resistor circuit allows accurate stipulation of the reference resistance value which is available in the entire integrated semiconductor circuit.

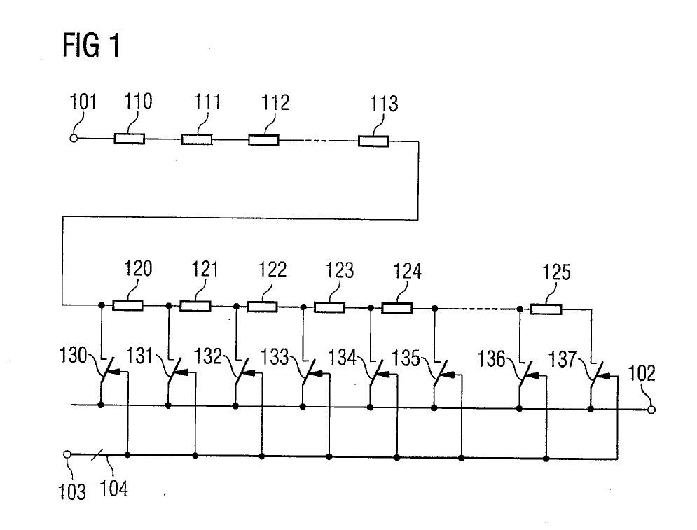

FIG. 1 shows the schematic illustration of a resistor circuit based on one embodiment. The resistor circuit has a resistor circuit input 101 and a resistor circuit output 102, and also a control word input 103, to which a control word supply line 104 is coupled. The resistor circuit input 101 is connected to a first nonswitchable resistor element 110. The first nonswitchable resistor element 110 is connected in series with further nonswitchable resistor elements 111, 112, 113. This series circuit connected in this manner is connected to the input of a first connectable resistor element 120. The output of the first connectable resistor 120 is connected to the input of a second connectable resistor element 121. The second connectable resistor element is connected in series with further connectable resistor elements 122, 123, 124 and with a final connectable resistor element 125. An output of the final connectable resistor element 125 is connected to the resistor circuit output 102.

The input of the first connectable resistor element 120 is also coupled to a first switching element 130, and the input of the second connectable resistor element 121 is coupled to a second switching element 131. The inputs of the further connectable resistor elements 122, 123, 124, 125 are respectively connected to a switching element 132, 133, 134, 135, 136. The output of the final connectable resistor element 125 is connected to the resistor circuit output 102 via a final switching element 137. The first switching element 130, the second switching element 131, and also all the other switching elements 132, 133, 134, 135, 136 and the final switching element 137 are all connected to the resistor circuit output 102. The switching elements 130 to 137 are connected to the control word input 103 via the control word supply line 104.

The total resistance value is stipulated by the digital control word which is applied to the control word input 103. If the first switching element 130 is closed, for example, then the series circuit comprising the nonswitchable resistor elements 110 to 113 is coupled to the resistor circuit output 102 directly via the first switching element 130. As a result, the total resistance value obtained for the resistor circuit is the sum of the individual resistance values of the nonswitchable resistor elements 110 to 113. If the first switching element 130 is open and the second switching element 131 is closed, for example, then the total resistance value for the present case is increased by the resistance value of the first connectable resistor element 120. Through suitable choice of control word, it is thus possible to choose a resistance value which is between the total sum of the nonswitchable resistor elements 110 to 113 and the total sum of all the connectable resistor elements 120 to 125.

The resistance values of the individual resistor elements may be chosen to be identical. It is likewise conceivable for the resistance values of the nonswitchable resistor elements 110 to 113 to be respectively greater than the resistance values of the connectable resistor elements 120 to 125.

In this case, it is also conceivable for the resistance values to be chosen such that the total resistance is linearly dependent on a binary control signal. This advantageously reduces the number of connectable resistor elements 120 to 125 which need to be provided. A dependency of this kind can be achieved through binary staggering of the resistance values of the connectable resistor elements 120 to 125 for example. By way of example, the first connectable resistor element 120 has a resistance value which is half a great as that of the second connectable resistor element 121, the second connectable resistor element has a resistance value which is half as great as that of the third connectable resistor element 122, etc. Alternatively, other codes and hence dependencies in the total resistance value of the resistor circuit on the digital control word are conceivable.

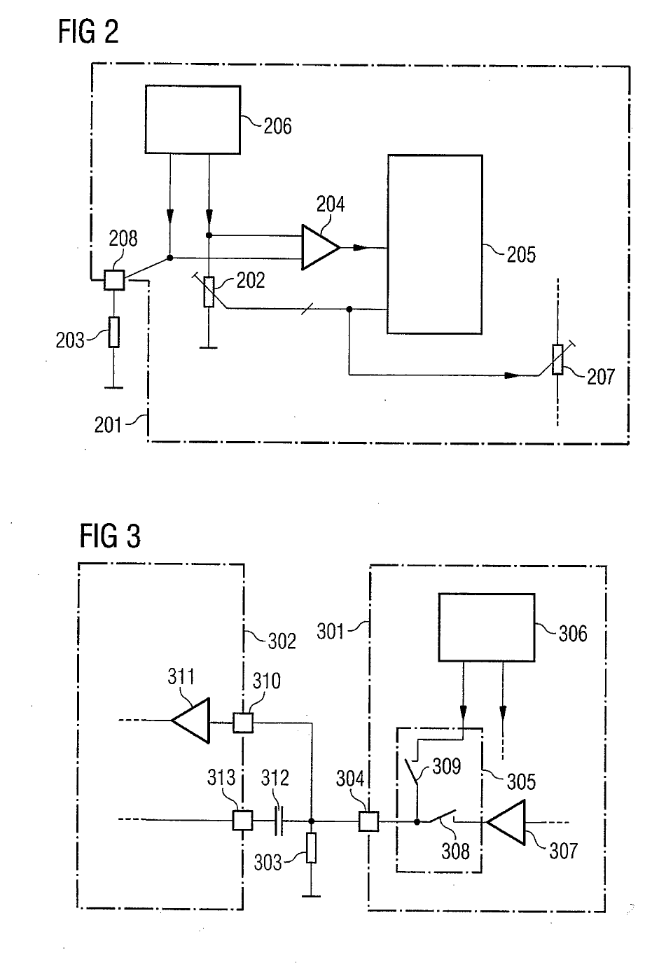

FIG. 2 shows an integrated semiconductor circuit 201 (shown in dashes) based on an embodiment.

The integrated semiconductor circuit 201 has a resistor circuit 202 which is in a form based on the embodiment shown in FIG. 1, for example.

The integrated circuit is coupled to an external resistor element 203. The first voltage applied to the resistor circuit can be compared with a second voltage applied to the external resistor element 203 by means of a comparator 204 which is in the form of a comparator circuit. To this end, the comparator 204 is coupled to the resistor circuit 202 and to the external resistor element 203. The output of the comparator 204 is coupled to a trimmer 205, the trimmer 205 being coupled to the resistor circuit 202 in order to provide it with the digital control word. In addition, a current source 206 is provided which is coupled to the resistor circuit 202 and to the external resistor 203. Since the resistor circuit 202 is additionally coupled to a ground connection, and the external resistor element 203 is likewise coupled to a second ground connection, the current provided by the current source 206 stipulates a first voltage applied to the resistor circuit and a second voltage applied to the external resistor element 203. In addition, the integrated semiconductor circuit 201 contains a second resistor circuit 207 which is coupled to the trimmer 205, so that the trimmer 205 can provide a second digital control word for the second resistor circuit 207 in order to set its total resistance value.

The external resistor element 203 is connected to the comparison apparatus 204 and to the current source 206 via a connection 208.

FIG. 3 shows the schematic illustration of a connection to the integrated semiconductor circuit based on an embodiment. In the exemplary illustrations, the integrated semiconductor circuit 301 is coupled to a further circuit 302. Provided between the integrated semiconductor circuit 301 and the further circuit 302 is the external resistor element 303. To couple the further circuit 302 and the external resistor element 303 to the integrated semiconductor circuit 301, the latter has a connection 304. The connection is coupled to a switching device 305 (shown in dashes) which can be used to couple the current source 306 to an element 307. To this end, the switching apparatus has a first switching element 308 and a second switching element 309.

The external resistor element 303 and the connection 304 are coupled to the further circuit 302. To this end, the further circuit 302 has a second connection 310 which is coupled to the external resistor element 303 and to the connection 304. In addition, the connection 304 and the external resistor are coupled to a third connection element of the further circuit 302 via a capacitance 312.

This allows the connection 304 to be used not only for determining the reference resistance by the external resistor element 303 but also as a normal connection for the integrated semiconductor circuit 301 to the further circuit 302. To ensure this, provision may be made for the second switching element 309 to be open, so that the voltage source 306 is decoupled from the external connection 304. If the first switching element 308 is closed, the driver element 307 provides a signal for the connection 304. This signal is then forwarded to the other circuits, for example via the connection 310 or the third connection 313.

If just the external resistor element 303 is connected to the external connection 304, the first switching element 308 is open and the second switching element 309 is closed then a defined current flows through the external resistor element 303 via the current source 306. To determine the reference resistance value accurately, the current source 306 is coupled to a comparison device and to a trimmer, as shown in FIG. 2, so that an internal resistor circuit in the integrated semiconductor circuit 301 can be tuned using the external resistor element 303.

Using the circuit shown in FIG. 3, it is possible both to connect the integrated semiconductor circuit 301 to an external second connection 310 of the further circuit 302, which connection has a particular nonreactive resistance, and to couple the connection 304 capacitively via the capacitance element 312 to a third connection 313 of the further circuit 302.

1. An integrated semiconductor circuit, comprising
a tunable resistor circuit whose total resistance value can be altered, the total resistance value being stipulated by a digital control word;
a comparator comparing a first voltage applied to the tunable resistor circuit with a second voltage applied to an external resistor element; and
a trimmer being coupled to the comparator and to the resistor circuit and providing the digital control word for the tunable resistor circuit; wherein the trimmer determines that digital control word for which the resistor circuit has a total resistance value at which the first voltage is in a prescribed ratio to the second voltage.

2. An integrated semiconductor circuit as claimed in according to claim 1, further comprising
a memory storing the digital control word.

3. An integrated semiconductor circuit according to claim 1, further comprising
a current source which can be coupled to the resistor circuit and to the external resistor element.

4. An integrated semiconductor circuit according to claim 3, further comprising
a connection which can be used to couple the external resistor element to the integrated semiconductor circuit, with the current source and the comparators apparatus being able to be connected to the connection.

5. An integrated semiconductor circuit according to claim 1, further comprising
a second resistor circuit whose second total resistance value can be altered and whose second total resistance value is stipulated by a second digital control word, the second digital control word being derived from the digital control word.

6. An integrated semiconductor circuit according to claim 1, wherein the tunable resistor circuit has a series circuit comprising resistor elements, and at least one resistor element is arranged in the series circuit so as to be able to be switched such that the resistance value of the resistor circuit can be altered by selecting a switching state.

7. An integrated semiconductor circuit, comprising
a digitally tunable resistor circuit controlled by a digital control word;
an external resistor element;
a comparator coupled with the digitally tunable resistor and the external resistor element for comparing voltages applied to the digitally tunable resistor and to the external resistor element; and
a digital control unit coupled to an output of the comparator and feeding the digital control word to the tunable resistor circuit;
wherein the digital control unit is operable to determine the digital control word for which the resistor circuit has a total resistance value at which the voltages are in a prescribed ratio.

8. An integrated semiconductor circuit according to claim 7, further comprising a memory storing the digital control word.

9. An integrated semiconductor circuit according to claim 7, further comprising a current source which can be coupled to the digitally controllable resistor circuit and to the external resistor element.

10. An integrated semiconductor circuit according to claim 9, further comprising a connection which can be used to couple the external resistor element to the integrated semiconductor circuit, with the current source and the comparator being able to be connected to the connection.

11. An integrated semiconductor circuit according to claim 7, further comprising a second digitally controllable resistor circuit whose second total resistance value is stipulated by a second digital control word, the second digital control word being derived from the digital control word.

12. An integrated semiconductor circuit according to claim 7, wherein the digitally tunable resistor circuit has a series circuit comprising resistor elements, and at least one resistor element is arranged in the series circuit so as to be able to be switched such that the resistance value of the resistor circuit can be altered by selecting a switching state.

13. An integrated semiconductor circuit, comprising
a first digitally tunable resistor circuit controlled by a first digital control word;
a second digitally tunable resistor circuit controlled by a second digital control word;
an external resistor element;
a comparator coupled with the first digitally tunable resistor and the external resistor element for comparing voltages applied to the first digitally tunable resistor and to the external resistor element; and
a digital control unit coupled to the comparator and to the first and second digitally tunable resistors for providing the first and second digital control word;
wherein the digital control unit is operable to determine the first digital control word for which the resistor circuit has a total resistance value at which the voltages are in a prescribed ratio, and to determine the second digital control word which is derived from the first digital control word.

14. An integrated semiconductor circuit according to claim 13, further comprising a memory storing the first and second digital control word.

15. An integrated semiconductor circuit according to claim 14, further comprising a current source which can be coupled to the first digitally controllable resistor circuit and to the external resistor element.

16. An integrated semiconductor circuit according to claim 15, further comprising a connection which can be used to couple the external resistor element to the integrated semiconductor circuit, with the current source and the comparator being able to be connected to the connection.

17. An integrated semiconductor circuit according to claim 13, wherein the first digitally tunable resistor circuit has a series circuit comprising resistor elements, and at least one resistor element is arranged in the series circuit so as to be able to be switched such that the resistance value of the first digitally tunable resistor circuit can be altered by selecting a switching state.
